(19) United States
(12) Patent Application Publication
(10) Pub. No.: US 2023/0353120 A1
(43) Pub. Date: Nov. 2, 2023

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Kentaro NAKAMURA, Nagaokakyo-shi (JP)

(21) Appl. No.: 18/208,383

(22) Filed: Jun. 12, 2023

Related U.S. Application Data
(63) Continuation of application No. PCT/JP2022/005639, filed on Feb. 14, 2022.

(30) Foreign Application Priority Data
Feb. 15, 2021 (JP) 2021-021851

(51) Int. Cl. H03H 9/13; H03H 9/02

(52) U.S. Cl. CPC H03H 9/131; H03H 9/02031; H03H 9/02102; H03H 9/132

(57) ABSTRACT

An acoustic wave device including a piezoelectric layer including lithium tantalate or lithium niobate, a dielectric film on the piezoelectric layer, and an IDT electrode on the dielectric film. The dielectric film includes one dielectric substance selected from the group consisting of TiO₂, TaO₂, MnO₂, GeO₂, RuO₂, OsO₂, IrO₂, SnO₂, and PbO₂.

### CROSS REFERENCE TO RELATED APPLICATIONS

This application claims the benefit of priority to Japanese Patent Application No. 2021-021851 filed on Feb. 15, 2021 and is a Continuation Application of PCT Application No. PCT/JP2022/005639 filed on Feb. 14, 2022. The entire contents of each application are hereby incorporated herein by reference.

### BACKGROUND OF THE INVENTION

### 1. Field of the Invention

The present invention relates to an acoustic wave device, such as an acoustic wave resonator or an acoustic wave filter.

### 2. Description of the Related Art

Acoustic wave devices that include a piezoelectric layer, an IDT electrode, and a silicon oxide film interposed therebetween are known in the related art. For example, in Japanese Patent No. 6766896, a piezoelectric layer is stacked directly on or indirectly above a high-acoustic velocity member. A silicon oxide film is disposed on the piezoelectric layer, and an IDT electrode is disposed on the silicon oxide film.

### SUMMARY OF THE INVENTION

The acoustic wave device described in Japanese Patent No. 6766896 includes a silicon oxide film in order to improve temperature characteristics. However, when a metal film was formed on a silicon oxide film as an IDT electrode, an epitaxial film could not be formed.

Accordingly, preferred embodiments of the present invention provide acoustic wave devices each including an IDT electrode that includes an epitaxial film.

An acoustic wave device according to a preferred embodiment of the present invention includes a piezoelectric layer including lithium tantalate or lithium niobate, a dielectric substance on the piezoelectric layer, and an IDT electrode on the dielectric substance, wherein the dielectric substance is one dielectric substance selected from the group consisting of TiO₂, TaO₂, MnO₂, GeO₂, RuO₂, OsO₂, IrO₂, SnO₂, and PbO₂.

According to a preferred embodiment of the present invention, since the specific dielectric substance described above is interposed between the piezoelectric layer and the IDT electrode, an IDT electrode including an electrode portion including an epitaxial film can be provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a front cross-sectional view of an acoustic wave device according to a first preferred embodiment of the present invention, illustrating the principal portions of the acoustic wave device.

FIG. 2 is a schematic plan view illustrating an electrode structure of the acoustic wave device according to the first preferred embodiment of the present invention.

FIG. 3 is a diagram illustrating the crystallinity of an IDT electrode included in an acoustic wave device prepared in a Comparative Example, which did not include a dielectric film.

FIG. 4 is a diagram illustrating the crystallinity of an IDT electrode included in an acoustic wave device prepared in an Example, which included a dielectric film.

### DETAILED DESCRIPTION OF THE PREFERRED EMBODIMENTS

Specific preferred embodiments of the present invention are described below with reference to the attached drawings below in order to clarify the present invention.

It should be noted that the preferred embodiments described herein are merely illustrative and the components can be partially replaced or combined with one another among different preferred embodiments.

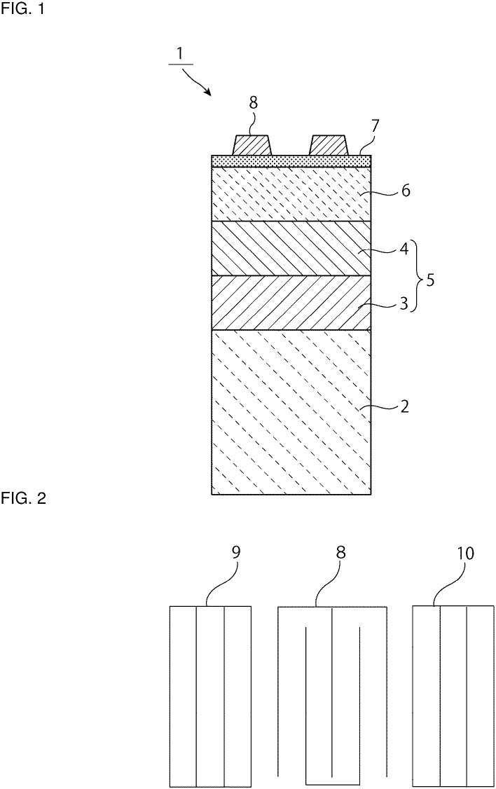

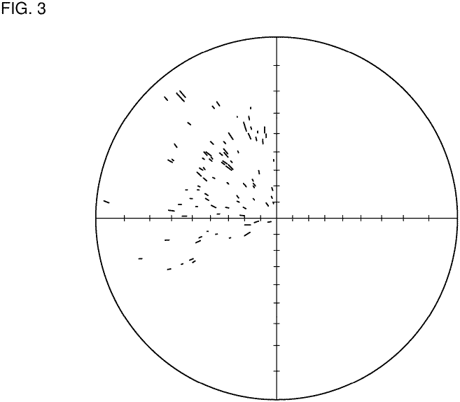

FIG. 1 is a front cross-sectional view of an acoustic wave device according to a first preferred embodiment of the present invention, illustrating the principal parts of the acoustic wave device. FIG. 2 is a schematic plan view illustrating an electrode structure of the acoustic wave device according to the first preferred embodiment of the present invention.

An acoustic wave device 1 includes a support substrate 2, a piezoelectric layer 6, and an intermediate layer 5 interposed therebetween. In this preferred embodiment, the support substrate 2 includes silicon. The support substrate 2 may include a semiconductor, such as silicon or silicon carbide, an appropriate dielectric substance, such as silicon nitride or aluminum oxide, or a piezoelectric material, such as aluminum nitride or quartz.

The intermediate layer 5 includes a multilayer body including a high-acoustic velocity film 3 and a low-acoustic velocity film 4. The high-acoustic velocity film 3 includes a high-acoustic velocity material through which a bulk wave propagates at an acoustic velocity higher than the acoustic velocity at which an acoustic wave propagates through the piezoelectric layer 6. The high-acoustic velocity material may be selected from various materials below: aluminum oxide, silicon carbide, silicon nitride, silicon oxynitride, silicon, sapphire, lithium tantalate, lithium niobate, quartz, alumina, zirconia, cordierite, mullite, steatite, forsterite, magnesia, a DLC (diamond-like carbon) film or diamond, a medium that includes any of the above materials as a principal component, and a medium that includes a combination of any of the above materials as a principal component.

In this preferred embodiment, the high-acoustic velocity film 3 includes a silicon nitride film.

The low-acoustic velocity film 4 includes a low-acoustic velocity material through which a bulk wave propagates at an acoustic velocity lower than the acoustic velocity at which a bulk wave propagates through the piezoelectric layer 6. In this preferred embodiment, the low-acoustic velocity film 4 includes silicon oxide.

The low-acoustic velocity material may be selected from various materials including silicon oxide, glass, silicon oxynitride, tantalum oxide, a compound produced by introducing fluorine, carbon, boron, hydrogen, or a silanol group to silicon oxide, and a medium that includes any of the above materials as a principal component.

In the case where the support substrate 2 includes the high-acoustic velocity material, the high-acoustic velocity film 3 may be omitted.

The piezoelectric layer 6 includes lithium tantalate or lithium niobate. In this preferred embodiment, the piezoelectric layer 6 includes 50°Y-cut X-propagation LiTaO₃.

Note that the crystallographic orientation of the piezoelectric layer 6 is not limited to this.

A dielectric film 7 is disposed on the piezoelectric layer 6. The dielectric film 7 includes one dielectric substance selected from the group consisting of TiO₂, TaO₂, MnO₂, GeO₂, RuO₂, OsO₂, IrO₂, SnO₂, and PbO₂. In this preferred embodiment, the dielectric film 7 includes TiO₂.

An IDT electrode 8 is disposed on the dielectric film 7.

While FIG. 1 illustrates only the portion in which a part of the IDT electrode 8 is disposed, the electrode structure of the acoustic wave device 1 includes the IDT electrode 8 and reflectors 9 and 10 disposed on the respective sides of the IDT electrode 8 in the direction in which an acoustic wave propagates, as illustrated in FIG. 2. Consequently, a one-port acoustic wave resonator is provided.

In the acoustic wave device 1, the dielectric film 7 includes the above-described specific dielectric substance material. Therefore, when the IDT electrode 8 is formed on the dielectric film 7, the metal film of the IDT electrode 8 is an epitaxial film.

Hereinafter, an Example and a Comparative Example are described to show that an IDT electrode was epitaxially grown in the Example.

In the Example, Si was used as a support substrate 2. The third Euler angle of orientation of the (100)-plane of Si was about 45°. A SiN film having a thickness of about 900 nm was used as a high-acoustic velocity film 3.

A SiO₂ film having a thickness of about 600 nm was used as a low-acoustic velocity film 4. As a piezoelectric layer 6, an approximately 50°Y-cut X-propagation LiTaO₃ was used. The thickness of the piezoelectric layer 6 was set to about 600 nm.

TiO₂ was used as a material of the dielectric film 7. The thickness of the dielectric film 7 was set to about 10 nm. The TiO₂ film was formed using an ALD apparatus.

The IDT electrode 8 was a multilayer body including Ti/Al/Ti films. The thicknesses of the Ti/Al/Ti films were set to Ti/Al/Ti = about 12/140/4 nm. Note that the Ti film of about 12 nm was the Ti film arranged to face the dielectric film 7.

The wavelength determined by the electrode finger pitch of the IDT electrode 8 was set to about 2 µm. The duty was set to about 0.5.

For comparison, an acoustic wave device of the Comparative Example was prepared as in Example, except that the TiO₂ film was omitted.

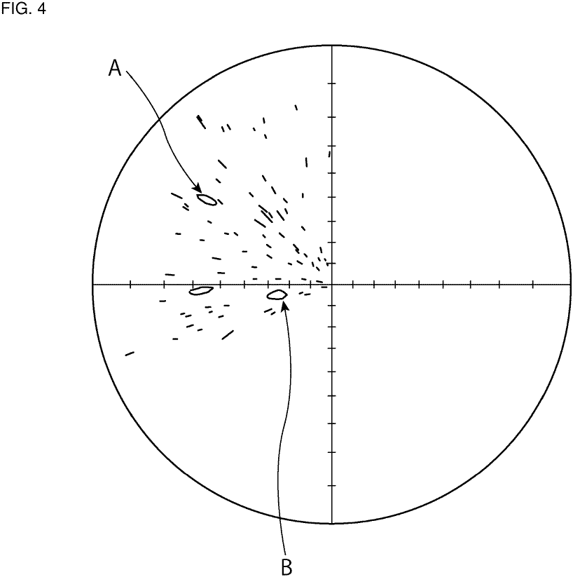

FIG. 3 is a diagram illustrating the crystallinity of an IDT electrode included in the acoustic wave device of Comparative Example. FIG. 4 is a diagram illustrating the crystallinity of an IDT electrode included in the acoustic wave device of the Example.

While the IDT electrode is not epitaxially grown in FIG. 3, as is clear from the portions denoted with the arrows A and B in FIG. 4, Al crystal alignment is confirmed in FIG. 4. Thus, it is confirmed that the IDT electrode is epitaxially grown.

A method in which the upper surface of a LiTaO₃ film is pickled and an IDT electrode is subsequently deposited thereon at high temperatures is known in the related art. Using this method, the IDT electrode can be formed as an epitaxial film. However, this method requires a complex pickling process.

In contrast, in the Example above, an IDT electrode excellent in terms of crystal alignment can be formed without performing such a pickling process.

Note that, in a preferred embodiment of the present invention, the upper surface of the piezoelectric layer 6 may be pickled. In such a case, the epitaxial property of the TiO₂ film can be further enhanced and, consequently, the epitaxial property of the IDT electrode 8 can be further improved.

The reasons for which interposing a TiO₂ film as a dielectric film 7 between the piezoelectric layer 6 and the IDT electrode 8 as described above enables the IDT electrode 8 to be formed as an epitaxial film are presumably as follows.

Table 1 below lists the crystal structure, lattice constant, oxygen interatomic distance on the Z-plane, and lattice misfit ratio relative to Ti (001) of LiTaO₃ and LiNbOs.

TABLE 1

| | LiNbO₃ | LiTaO₃ |
|---|---|---|
| Crystal structure | Trigonal | Trigonal |
| Lattice constant | a = 5.148 Å c = 13.863 Å | a = 5.154 Å c = 13.783 Å |
| Oxygen interatomic distance on Z-plane | 2.972 Å | 2.976 Å |
| Lattice misfit ratio to Ti(001) | 0.71% | 0.84% |

In the acoustic wave device 1, the dielectric film 7 includes TiO₂, and the piezoelectric layer 6 includes LiTaO₃. The oxygen interatomic distance on the Z-plane of LiTaO₃ is about 2.976 Å, while the oxygen interatomic distance of TiO₂ is about 2.9575 Å. Lattice misfit ratio is expressed as { (d_{L} - d_{U}) /d_{L}} × 100, where d_{L} is the oxygen interatomic distance on the Z-plane of LiTaO₃ and d_{U} is the lattice constant of TiO₂.

The lattice constant of Ti(001) is about 2.951 Å, and the lattice constant of Al (111) is about 2.864 Å.

The multilayer structure of the acoustic wave device 1 includes Ti/Al/Ti(multilayer electrode layer) /TiO_{2/}LiTaO₃. Thus, the lattice misfit ratios at the interfaces present in the region extending from the Al layer of the IDT electrode 8 to LiTaO₃ are approximately Al-Ti (2.95%) //Ti-TiO₂ (0.22%) //TiO₂-LiTaO₃ (0.62%).

On the other hand, in the Comparative Example where the TiO₂ film was not formed, the multilayer structure is constituted by Ti/Al/Ti(multilayer electrode layer) /LiTaO₃. In this case, the lattice misfit ratios are approximately Al-Ti (2.95%)//Ti-LiTaO₃ (0.84%).

That is, in the Comparative Example, the lattice misfit ratio between LiTaO₃ which defines and functions as a piezoelectric layer and the Ti film of the IDT electrode is high (about 0.84%). In contrast, in the acoustic wave device 1, the lattice misfit ratio between LiTaO₃ which defines and functions as a piezoelectric layer 6 and the TiO₂ film which defines and functions as a dielectric film 7 is low (about 0.62%) . This enables the TiO₂ film to be formed as an epitaxial film. Thus, when an IDT electrode 8, that is, a Ti film and an Al film, are formed on the dielectric film 7, the Ti and Al films can be formed as epitaxial films.

In the acoustic wave device described in Japanese Patent No. 6766896, a silicon oxide film is used as a dielectric film. In the case where an IDT electrode is formed on a silicon oxide film at high temperatures, an IDT electrode cannot be epitaxially grown. This is presumably because the lattice misfit ratio between silicon oxide and LiTaO₃ is considerably high (100% or more).

As described above, when the lattice misfit ratio between LiTaO₃ and the dielectric film 7 is low, the dielectric film 7 can be epitaxially grown and, furthermore, the IDT electrode 8 can be epitaxially grown. Examples of the dielectric substance include TiO₂, TaO₂, MnO₂, GeO₂, RuO₂, OsO₂, IrO₂, SnO₂, and PbO₂. Table 2 below lists examples of lattice misfit ratios between the above materials and the Z-plane of LiTaO₃.

TABLE 2

| | | Lattice misfit ratio (%) |
|---|---|---|
| Z-plane of LiTaO₃ | TiO₂ (001) | 0.57 |
| | TaO₂ (001) | 2.99 |
| | MnO₂(β) (001) | 3.46 |
| | GeO₂ (001) | 3.90 |

In a preferred embodiment of the present invention, the piezoelectric layer 6 may include LiNbO₃. As listed in Table 1 above, in the case where LiNbO₃ is used, the oxygen interatomic distance on the Z-plane is about 2.972 Å. Thus, although the lattice misfit ratio relative to Ti(001) is high (about 0.71%), the lattice misfit ratio between TiO₂ and LiNbO₃ is approximately {(2.972 - 2.9575)/2.972} × 100 = 0.49%, which is lower than about 0.71%. Thus, even in the case where lithium niobate is used as a piezoelectric layer 6, the dielectric film 7 can be epitaxially grown and the IDT electrode 8 can be formed as an epitaxial film as in the above-described preferred embodiment.

The above-described dielectric substance is preferably one selected from the group consisting of TiO₂, TaO₂, MnO₂, and GeO₂ and is further preferably TiO₂.

Note that the electrode portion of the IDT electrode 8 which is in contact with the dielectric film 7 may include Pt, although it includes Ti in the above-described preferred embodiment. The electrode portion preferably includes Ti or Pt. The other electrode portion above the electrode portion that is in contact with the dielectric film 7 may include a metal, such as Al, AlCu, or W, or an alloy.

While the electrode portion of the IDT electrode 8 which is in contact with the dielectric film 7 is formed as an epitaxial film, an Al film or an AlCu film stacked on the electrode portion may be formed as an epitaxial film due to the impacts of the epitaxial property of the base layer.

In the acoustic wave device 1, the intermediate layer 5 is interposed between the support substrate 2 and the piezoelectric layer 6. The intermediate layer 5 may be an acoustic reflection layer including a multilayer body including a low-acoustic impedance layer and a high-acoustic impedance layer.

In the acoustic wave device 1 according to a preferred embodiment of the present invention, the piezoelectric layer 6 may be a piezoelectric substrate including lithium tantalate or lithium niobate. In other words, the intermediate layer 5 and the support substrate 2 are optional and can be omitted.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including lithium tantalate or lithium niobate;
a dielectric substance on the piezoelectric layer; and
an IDT electrode on the dielectric substance; wherein
the dielectric substance is one dielectric substance selected from the group consisting of TiO₂, TaO₂, MnO₂, GeO₂, RuO₂, OsO₂, IrO₂, SnO₂, and PbO₂.

2. The acoustic wave device according to claim 1, wherein the dielectric substance is one dielectric substance selected from the group consisting of TiO₂, TaO₂, MnO₂, and GeO₂.

3. The acoustic wave device according to claim 2, wherein the dielectric substance is TiO₂.

4. The acoustic wave device according to claim 1, wherein an electrode portion of the IDT electrode is in contact with the dielectric substance.

5. The acoustic wave device according to claim 4, wherein the electrode portion of the IDT electrode includes an epitaxial film.

6. The acoustic wave device according to claim 1, wherein the IDT electrode includes an epitaxial film.

7. The acoustic wave device according to claim 1, further comprising an intermediate layer on a side opposite to a side on which the dielectric substance is located, and a support substrate on a side of the intermediate layer which is opposite to a side of the intermediate layer on which the piezoelectric layer is located; wherein
the intermediate layer includes a low-acoustic velocity film including a low-acoustic velocity material through which a bulk wave propagates at an acoustic velocity lower than an acoustic velocity at which a bulk wave propagates through the piezoelectric layer.

8. The acoustic wave device according to claim 7, wherein the intermediate layer further includes a high-acoustic velocity film interposed between the low-acoustic velocity film and the support substrate, the high-acoustic velocity film being including a high-acoustic velocity material through which a bulk wave propagates at an acoustic velocity higher than an acoustic velocity at which an acoustic wave propagates through the piezoelectric layer.

9. The acoustic wave device according to claim 7, wherein the support substrate includes a high-acoustic velocity material through which a bulk wave propagates at an acoustic velocity higher than an acoustic velocity at which an acoustic wave propagates through the piezoelectric layer.

10. The acoustic wave device according to claim 1, wherein the piezoelectric layer is a piezoelectric substrate including lithium tantalate or lithium niobate.

11. The acoustic wave device according to claim 1, wherein the support substate includes silicon.

12. The acoustic wave device according to claim 1, wherein the substrate includes a semiconductor material or a piezoelectric material.

13. The acoustic wave device according to claim 8, wherein the high-acoustic velocity film includes aluminum oxide, silicon carbide, silicon nitride, silicon oxynitride, silicon, sapphire, lithium tantalate, lithium niobate, quartz, alumina, zirconia, cordierite, mullite, steatite, forsterite, magnesia, a diamondlike carbon film or diamond.

14. The acoustic wave device according to claim 1, wherein the low-acoustic velocity film includes silicon oxide, glass, silicon oxynitride, tantalum oxide, or a compound including fluorine, carbon, boron, hydrogen, or a silanol group and silicon oxide.

15. The acoustic wave device according to claim 1, wherein the piezoelectric layer includes the piezoelectric layer includes 50°Y-cut X-propagation LiTaO₃.

16. The acoustic wave device according to claim 1, further comprising reflectors on both sides of the IDT electrode.

17. The acoustic wave device according to claim 1, wherein the acoustic wave device is a one-port acoustic wave resonator.

18. The acoustic wave device according to claim 8, wherein the high-acoustic velocity film includes a silicon nitride film.

19. The acoustic wave device according to claim 7, wherein the low-acoustic velocity film includes silicon oxide.

20. The acoustic wave device according to claim 4, further comprising an Al film or an AlCu film on the electrode portion.
